(19) United States
(12) Patent Application Publication
(10) Pub. No.: US 2026/0260688 A1
(43) Pub. Date: Sep. 3, 2026

(54) NON-VOLATILE MEMORY AND PROGRAMMING METHOD THEREOF

(71) Applicant: MACRONIX International Co., Ltd., Hsinchu (TW)

(72) Inventors: Ya-Jui Lee, Taichung City (TW); Kuan-Fu Chen, Taipei City (TW)

(73) Assignee: MACRONIX International Co., Ltd., Hsinchu (TW)

(21) Appl. No.: 19/067,992

(22) Filed: Mar. 3, 2025

(51) Int. Cl. G11C 11/56; G11C 16/04; G11C 16/10; G11C 16/34

(52) U.S. Cl. CPC G11C 11/5628; G11C 11/5671; G11C 16/0483; G11C 16/10; G11C 16/3459

(57) ABSTRACT

Provided is a non-volatile memory and a programming method thereof. The non-volatile memory may be a three-dimensional NAND flash memory with high capacity and high performance. The non-volatile memory includes a memory cell array and a control circuit. During a programming period for programming multiple memory cells of a current word line, the control circuit reads at least one threshold voltage of at least one neighboring word line adjacent to the current word line. The control circuit checks the at least one threshold voltage of the at least one neighboring word line to generate a check result. According to the check result, the control circuit adjusts a programming verification voltage used to verify the current word line during the programming period.

### BACKGROUND

### Technical Field

This disclosure relates to a memory device, and in particular to a non-volatile memory (such as a three-dimensional NAND flash memory) and a programming method thereof.

### Description of Related Art

The development of integrated circuit (IC) memory containing high capacity and high performance 3D NAND flash memory is continuing. To overcome the problem of shrinking dimensions, the NAND flash memory industry has transitioned from planar to 3D architectures. The storage capacity of 3D vertical NAND flash memory has been increasing over the past decade to meet the needs of various industries including mobile and data centers. The increase in the number of stacked word-line (WL) layers has played a key role in enabling higher storage capacity or bit density. This paradigm shift allows for increased storage density through vertical stacking of storage units rather than relying solely on cell miniaturization. Charge-trap technology uses a continuous silicon nitride layer as the storage node (SN). Compared with floating gate technology, charge-trap technology is widely used in 3D NAND flash memory arrays due to its simpler process and higher vertical scaling capability. However, as the number of stack layers increases, the read VT window becomes worse. Tightening the width of the threshold voltage (VT) distribution of triple-level cells (TLC) or quad-level cells (QLC) in the threshold voltage (VT) distribution graph is one of the many technical issues in 3D NAND.

### SUMMARY

The disclosure provides a non-volatile memory and a programming method thereof.

In an embodiment of the disclosure, the non-volatile memory includes a memory cell array and a control circuit. The memory cell array has multiple memory cells. Each of multiple word lines is coupled to multiple memory cells in a corresponding row of the memory cells. Each of multiple bit lines is coupled to multiple memory cells in a corresponding column of the memory cells. The control circuit is coupled to the memory cell array. During a programming period for programming multiple memory cells of a current word line among the word lines, the control circuit reads at least one threshold voltage (VT) of at least one neighboring word line adjacent to the current word line among the word lines. The control circuit checks the at least one threshold voltage of the at least one neighboring word line to generate a check result. Based on the check result, the control circuit adjusts a programming verification voltage used to verify the current word line during the programming period.

In an embodiment of the disclosure, the programming method is adapted for a non-volatile memory. The programming method includes the following. At least one threshold voltage of at least one neighboring word line adjacent to a current word line is read during a programming period for programming multiple memory cells of the current word line. The at least one threshold voltage of the at least one neighboring word line is checked to generate a check result. A programming verification voltage used to verify the current word line is adjusted during the programming period based on the check result.

Based on the above, during the programming period of programming the memory cells of the current word line, the control circuit described in the embodiments of the disclosure can read the threshold voltage state of the memory cells of the neighboring word line. The control circuit determines whether to adjust the programming verification voltage used to verify the current word line in the programming period according to the threshold voltage of the memory cell of the neighboring word line. For example, in response to the threshold voltage of the neighboring word line being judged to be high, the control circuit selects the low verification voltage as the programming verification voltage of the current word line. On the contrary, in response to the threshold voltage of the neighboring word line being judged to be low, the control circuit selects the high verification voltage as the programming verification voltage of the current word line. By adjusting the programming verification voltage, the control circuit effectively tightens the width of the threshold voltage distribution of the memory cell, thereby improving data retention thereof.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate example embodiments of the disclosure and, together with the description, serve to explain the principles of the disclosure.

FIG. 1 is a circuit block schematic diagram of a non-volatile memory according to an embodiment of the disclosure.

FIG. 2 is a three-dimensional schematic diagram of a memory cell string in a non-volatile memory according to an embodiment of the disclosure.

FIG. 3 is a schematic diagram of multiple threshold voltage (VT) distributions according to an embodiment of the disclosure, using a memory cell in the form of a triple-level cell (TLC) as an example.

FIG. 4 is a schematic diagram of threshold voltage distribution of a current word line affected by a neighboring word line according to an embodiment of the disclosure, using a memory cell in the form of a triple-level cell (TLC) as an example.

FIG. 5 is a flow chart of a programming method of a non-volatile memory according to an embodiment of the disclosure.

FIG. 6 is a schematic diagram of threshold voltage distribution of a word line according to another embodiment of the disclosure, using a memory cell in the form of a triple-level cell (TLC) as an example.

FIG. 7 is a flow chart of a programming method of a non-volatile memory according to yet another embodiment of the disclosure.

FIG. 8 is a schematic diagram of waveforms of a word line and a bit line according to an embodiment of the disclosure.

FIG. 9 is a schematic diagram of waveforms of a word line and a bit line according to another embodiment of the disclosure.

FIG. 10 is a flow chart of a programming method of a non-volatile memory according to another embodiment of the disclosure.

### DESCRIPTION OF THE EMBODIMENTS

The word “coupling (or connecting)” used throughout the specification of this application (including the claims) can refer to any direct or indirect connection means. For example, if a first device is described as being coupled (or connected) to a second device, it should be interpreted as meaning that the first device can be directly connected to the second device, or that the first device can be connected indirectly to the second device through other devices or some connection means. The terms “first” and “second” mentioned in the full text of the specification of this application (including the claims) are used to name elements or to distinguish between different embodiments or scopes, and are not intended to limit the upper or lower limit of the number of elements, or the order of the elements. In addition, wherever possible, elements/components/steps with the same reference numerals are used in the drawings and embodiments to represent the same or similar parts. Elements/components/steps using the same reference numerals or using the same terms in different embodiments can refer to the relevant descriptions of each other.

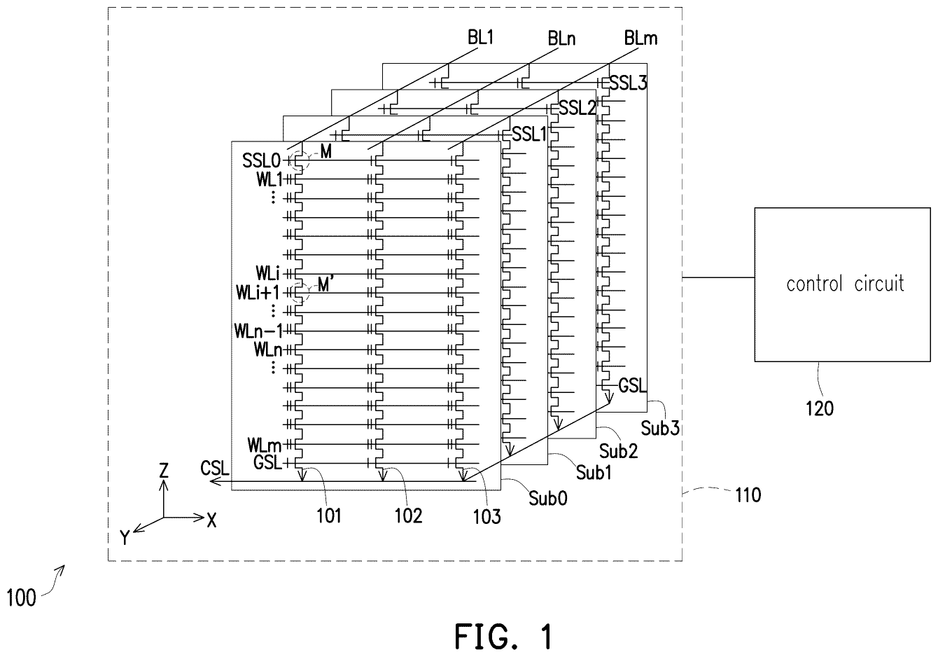

FIG. 1 is a circuit block schematic diagram of a non-volatile memory 100 according to an embodiment of the disclosure. The non-volatile memory 100 includes a memory cell array 110 and a control circuit 120. The control circuit 120 is coupled to the memory cell array 110. According to different designs, in some embodiments, the control circuit 120 may be implemented as a hardware circuit. In other embodiments, the control circuit 120 may be implemented in the form of a combination of more than one of hardware, firmware, and software (i.e., program).

In the form of hardware, the control circuit 120 can be implemented as a logic circuit on an integrated circuit. For example, the related functions of the control circuit 120 may be implemented in one or more hardware controllers, microcontrollers, hardware processors, microprocessors, Application-specific integrated circuit (ASIC), digital signal processor (DSP), Field Programmable Gate Array (FPGA), Central Processing Unit (CPU), and/or various logical blocks, modules, and circuits in other processing units. The related functions of the control circuit 120 can be implemented as hardware circuits, such as various logical blocks, modules, and circuits in integrated circuits, using hardware description languages (such as Verilog HDL or VHDL) or other suitable programming languages.

In terms of software and/or firmware, the related functions of the control circuit 120 can be implemented as programming codes. For example, the control circuit 120 is implemented using general programming languages (such as C, C++, or combinatorial language) or other suitable programming languages. The programming code can be recorded/stored in a “non-transitory machine-readable storage medium”. In some embodiments, the non-transitory machine-readable storage medium includes, for example, a semiconductor memory and/or a storage device. Electronic devices (such as CPUs, hardware controllers, microcontrollers, hardware processors, or microprocessors) can read and execute the programming code from the non-transitory machine-readable storage medium, thereby realizing related functions of the control circuit 120.

FIG. 1 shows an equivalent circuit of a three-dimensional (3D) NAND flash memory in a three-dimensional (3D) manner. The memory cell array 110 has multiple memory cells (for example, memory cells M′). The multiple memory cells in the memory cell array 110 shown in FIG. 1 are arranged in a 3D manner in the XYZ coordinate system. However, this does not mean that the circuit of the memory cell array 110 is limited to the 3D manner. In one example, the memory cell array 110 may be divided into four sub-blocks Sub0, Sub1, Sub2, and Sub3. The control circuit 120 can independently control the operation of each sub-block (such as the sub-block Sub0).

Each memory cell string (e.g., memory cell strings 101, 102, or 103) shown in FIG. 1 includes multiple memory cells (e.g., memory cells M′) connected in series in the Z direction. The memory cell array 110 includes multiple word lines (WL), such as word lines WL1, . . . , WLi, WLi+1, . . . , WLn−1, WLn, . . . , WLm shown in FIG. 1. One word line (e.g., the word line WLn) may correspond to a layer in the XY plane. Each of the word lines WL1 to WLm is coupled to multiple memory cells in a corresponding row of the memory cells. Multiple memory cells in each memory cell string (e.g., the memory cell string 101) correspond to one word line (e.g., the word line WLi+1). The memory cell M may be configured as a string select transistor coupled to a string select line (SSL, such as string select lines SSL0, SSL1, SSL2, and SSL3), and another memory cell may be configured as a ground select transistor coupled to a ground select line (GSL). The string select transistor and the ground select transistor are located on opposite sides of each memory cell string (e.g., the memory cell string 101). In this example, multiple memory cell strings (e.g., the memory cell strings 101, 102, etc.) coupled to the same string select line (e.g., the string select line SSL0) on the same plane (e.g., the plane defined by the X direction and the Z direction) can be defined as a sub-block (e.g., the sub-block Sub0).

Each of multiple bit lines (BL) is coupled to multiple memory cells in a corresponding column of the memory cells. That is, each memory cell string (e.g., the memory cell string 101, 102, or 103) is connected to the corresponding bit line (e.g., bit lines BL1, BLn, or BLm) through the corresponding string select transistor on the string select line (e.g., the string select line SSL0). The memory cell string (e.g., the memory cell string 101) of the same row in different sub-blocks (e.g., the sub-blocks Sub0, Sub1 . . . , etc.) in the Y direction are connected to the corresponding bit line (e.g., the bit line BL1). The string select line (e.g., the string select line SSL0) may be a conductive line or conductive layer formed over the uppermost word line layer (e.g., the word line WL1). Each memory cell string (e.g., the memory cell string 101, 102, or 103) may be connected to the same common source line CSL through a corresponding ground select transistor on the ground select line GSL. The ground select line GSL may be a conductive line or conductive layer formed under the lowest word line layer (e.g., the word line WLm). The common source line CSL may be a conductive layer formed over the substrate of the non-volatile memory 100. The string select lines (e.g., the string select lines SSL0 to SSL3) in the memory cell array 110 can be on the same conductive layer, but divided into independent wirings. Each independent wiring (string select line) can independently control the operation of the corresponding sub-block (e.g., the sub-block Sub0, Sub1 . . . etc.) in the memory cell array 110.

In an example, in a single level cell (SLC) mode, multiple memory cells (including the memory cells M′) in a sub-region (e.g., the sub-region Sub0) coupled to the same word line or word line layer (e.g., the word line WLn) can be defined as a page. In another example, in a triple-level cell (TLC) mode, multiple memory cells (including the memory cells M′) in a sub-region (e.g., the sub-region Sub0) coupled to the same word line or word line layer (e.g., the word line WLn) can be defined as three pages. In TLC mode, the three pages include high page, middle page, and low page. The same voltage is applied to the memory cells M′ located on the same word line (e.g., the word line WLn). Each word line (e.g., the word line WLn) can be connected to a driver circuit, such as an X-decoder (or scan driver).

In an example, one or more dummy lines or layers (not shown) can be disposed between the string select lines (e.g., the string select lines SSL0 to SSL3) and the word line layer (e.g., the word line WL1), and between the ground select line GSL and the lowest word line layer (e.g., the word line WLm). In another example, one or more dummy lines or layers (not shown) may be disposed in the middle portion of each memory cell string (e.g., the memory cell string 101, 102, or 103). The non-volatile memory 100 also includes a control circuit 120 to implement corresponding operations on the memory cell array 110.

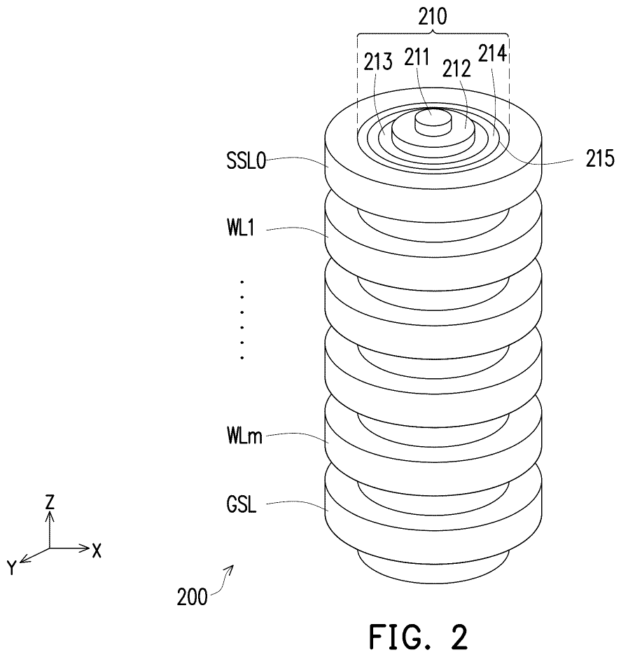

This embodiment does not limit the specific implementation of each memory cell string (e.g., the memory cell string 101, 102 or 103) of the memory cell array 110. For example, FIG. 2 is a three-dimensional schematic diagram of a memory cell string 200 in a non-volatile memory according to an embodiment of the disclosure. The memory cell string 200 shown in FIG. 2 can be used as one of many implementation examples of each memory cell string (e.g., the memory cell string 101, 102, or 103) in the memory cell array 110 shown in FIG. 1.

The memory cell string 200 includes a channel pillar structure 210 and multiple word lines WL0 to WLm formed by multiple metal layers. FIG. 2 shows multiple memory cells (e.g., memory cells M′) located at the intersection of the channel pillar structure 210 of the 3D NAND storage device (the non-volatile memory 100) and each word line layer (gate layer) WL0 to WLm). The multiple memory cells M′ are connected in series along the channel pillar structure 210 in the Z direction. The channel pillar structure 210 includes a dielectric core 211, a channel layer 212, a tunneling layer 213, and a charge trapping layer 214. The dielectric core 211 is, for example, an oxide filler pillar or other dielectric material. The dielectric core 211 is surrounded by the channel layer 212. The channel layer 212 is, for example, a polysilicon channel layer or other materials.

The channel layer 212 is surrounded by multilayer dielectric material. The multilayer dielectric material includes a tunneling layer 213 (e.g., oxide), a charge trapping layer 214 (e.g., nitride), and a blocking layer 215 (e.g., oxide). The charge trapping layer 214 surrounds the channel layer 212. The dielectric core 211, the channel layer 212, and the charge trapping layer 214 extend in the Z direction and form a channel pillar structure 210. Memory cells in the same channel pillar structure 210 can form a memory cell string 200. The blocking layer 215 surrounds the outer surface of the charge trapping layer 214. The blocking layer 215 is located between the charge trapping layer 214 and the word line layers (gate layers) WL0 to WLm.

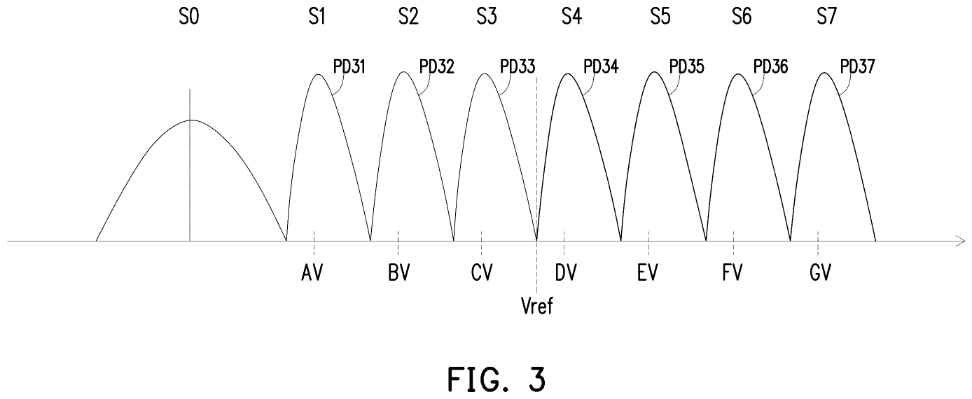

FIG. 3 is a schematic diagram of multiple threshold voltage (VT) distributions according to an embodiment of the disclosure, using a memory cell in the form of a triple-level cell (TLC) as an example. The horizontal axis of FIG. 3 represents voltage, while the vertical axis represents the number or probability of memory cells. FIG. 3 shows threshold voltage distributions of multiple memory cells after programmed operation. The threshold voltage distributions can be divided into an erasure state S0 and potential states S1, S2, S3, S4, S5, S6, and S7. The potential states S1 to S7 can be programmed by reference voltage (programming verification voltage) AV, BV, CV, DV, EV, FV, and GV. Distribution curves PD31, PD32, PD33, PD34, PD35, PD36, and PD37 shown in FIG. 3 represent the threshold voltage distributions of the potential states S1 to S7.

The width of a read window of a current word line (e.g., the word line WLn) is closely related to the data pattern of at least one neighboring word line (e.g., the word line WLn−1) adjacent to the current word line. Due to charge lateral spreading, the low threshold voltage (VT) of the memory cells on the neighboring word line (e.g., WLn−1 or WLn+1) results in a higher loss of charge of the memory cell on the current word line (e.g., the word line WLn), which in turn results in a lower threshold voltage (VT) of the memory cell on the current word line.

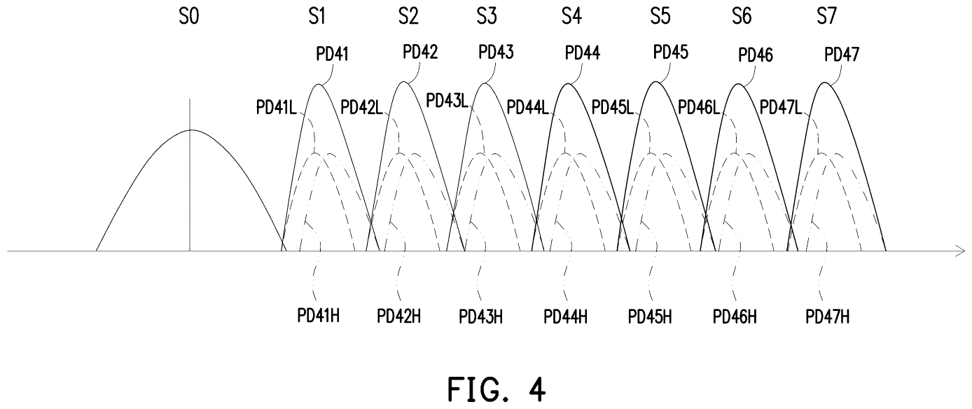

FIG. 4 is a schematic diagram of threshold voltage (VT) distribution of a current word line (e.g., the word line WLn) affected by a neighboring word line (e.g., WLn−1 or WLn+1) according to an embodiment of the disclosure, using a memory cell in the form of a triple-level cell (TLC) as an example. The horizontal axis of FIG. 4 represents voltage, while the vertical axis represents the number or probability of memory cells. FIG. 4 shows threshold voltage distribution curves PD41, PD42, PD43, PD44, PD45, PD46, and PD47 of the potential states S1 to S7 of multiple memory cells after programmed operation.

The width of the read window of the current word line (e.g., the word line WLn) is closely related to the data pattern of at least one neighboring word line (e.g., the word line WLn−1) adjacent to the current word line. When the memory cell on the neighboring word line (e.g., WLn−1 or WLn+1) has a low threshold voltage (VT), the neighboring word line results in a lower threshold voltage (VT) on the memory cell on the current word line (e.g., the word line WLn), as shown in FIG. 4 for threshold voltage distribution curves PD41L, PD42L, PD43L, PD44L, PD45L, PD46L, and PD47L. When the memory cell on the neighboring word line (e.g., WLn−1 or WLn+1) has a high threshold voltage (VT), the neighboring word line causes a higher threshold voltage (VT) on the memory cell on the current word line (e.g., the word line WLn), as shown in FIG. 4 for threshold voltage distribution curves PD41H, PD42H, PD43H, PD44H, PD45H, PD46H, and PD47H. Therefore, the widths of the threshold voltage distribution curves PD41 to PD47 become larger. The following embodiments illustrate how to adjust programming verification voltage AV to GV used to verify the current word line in the programming period to tighten the threshold voltage (VT) distribution width in the threshold voltage distribution diagram.

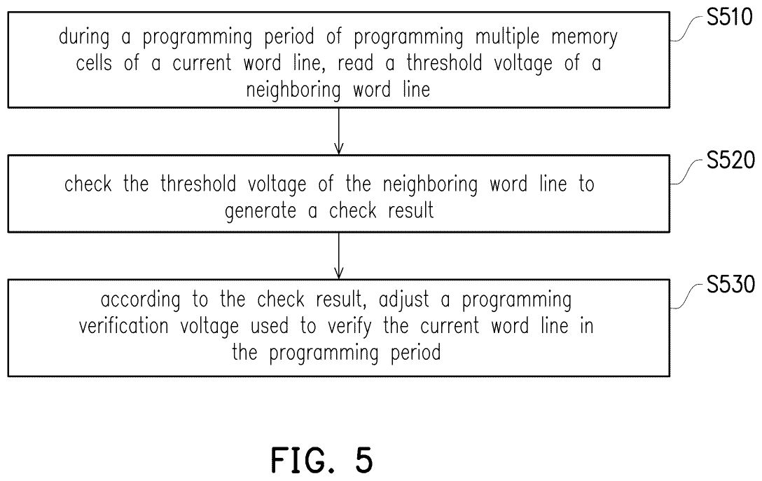

FIG. 5 is a flow chart of a programming method of a non-volatile memory according to an embodiment of the disclosure. The programming method described in FIG. 5 can be implemented by the non-volatile memory 100 in FIG. 1. The programming method described in FIG. 5 can be applied to memory devices with different memory cell forms. The multiple memory cells in the memory cell array 110 shown in FIG. 1 may be multi-level memory cells. The multi-level type may be one of a multi-level cell (MLC) type, a triple-level cell (TLC) type, and a quad-level memory cell (QLC) type. Please refer to FIG. 1 and FIG. 5. During the programming period of programming multiple memory cells of the current word line (e.g., the word line WLn), the control circuit 120 reads at least one threshold voltage of at least one neighboring word line adjacent to the current word line (step S510). In step S520, the control circuit 120 checks the at least one threshold voltage of the at least one neighboring word line to generate a check result. According to the check result, the control circuit 120 adjusts the programming verification voltage used to verify the current word line in the programming period (step S530).

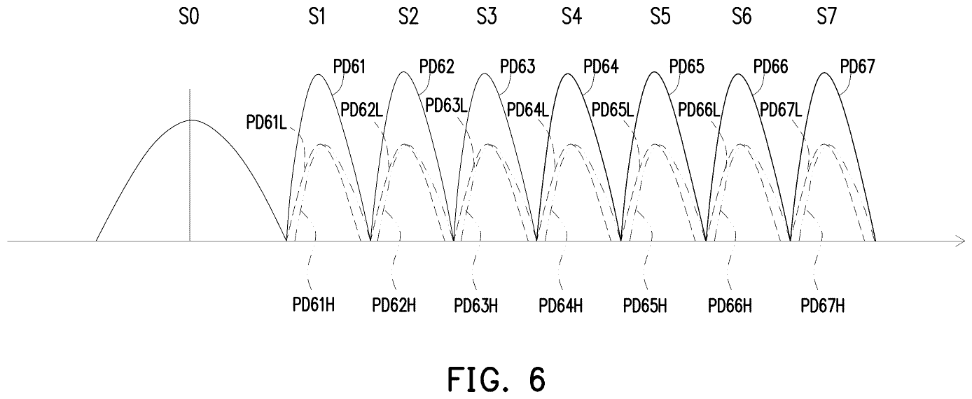

FIG. 6 is a schematic diagram of threshold voltage distribution of a word line according to another embodiment of the disclosure, using a memory cell in the form of a triple-level cell (TLC) as an example. The horizontal axis of FIG. 6 represents voltage, while the vertical axis represents the number or probability of memory cells. FIG. 6 shows threshold voltage distribution curves PD61, PD62, PD63, PD64, PD65, PD66, and PD67 of the potential states S1 to S7 of multiple memory cells after programmed operation. When the memory cell on the neighboring word line (e.g., WLn−1 or WLn+1) is judged to have a low threshold voltage (VT), the control circuit 120 selects high verification voltage as the programming verification voltages AV to GV of the current word line (e.g., WLn). As shown in FIG. 6, the threshold voltage distribution curves PD61L, PD62L, PD63L, PD64L, PD65L, PD66L, and PD67L are moved to the right (compared to the threshold voltage distribution curves PD41L to PD47L shown in FIG. 4).

When the memory cell on the neighboring word line (e.g., WLn−1 or WLn+1) has a high threshold voltage (VT), the control circuit 120 selects low verification voltage as the programming verification voltage AV to GV of the current word line (e.g., WLn). As shown in FIG. 6, the threshold voltage distribution curves PD61H, PD62H, PD63H, PD64H, PD65H, PD66H, and PD67H are moved to the left (compared to the threshold voltage distribution curves PD41H to PD47H shown in FIG. 4). Therefore, compared with the threshold voltage distribution curve PD41 to PD47 shown in FIG. 4, the width of the threshold voltage distribution curve PD61 to PD67 shown in FIG. 6 is effectively tightened.

To sum up, during the programming period of programming the memory cells of the current word line, the control circuit 120 can read the threshold voltage state of the memory cells of the neighboring word line. The control circuit 120 determines whether to adjust the programming verification voltage used to verify the current word line in the programming period according to the threshold voltage (VT) of the memory cell of the neighboring word line. For example, in response to the threshold voltage of the neighboring word line being judged to be high, the control circuit 120 selects the low verification voltage as the programming verification voltage of the current word line. On the contrary, in response to the threshold voltage of the neighboring word line being judged to be low, the control circuit 120 selects the high verification voltage as the programming verification voltage of the current word line. By adjusting the programming verification voltage, the control circuit 120 effectively tightens the width of the threshold voltage distribution of the memory cell, thereby improving data retention thereof.

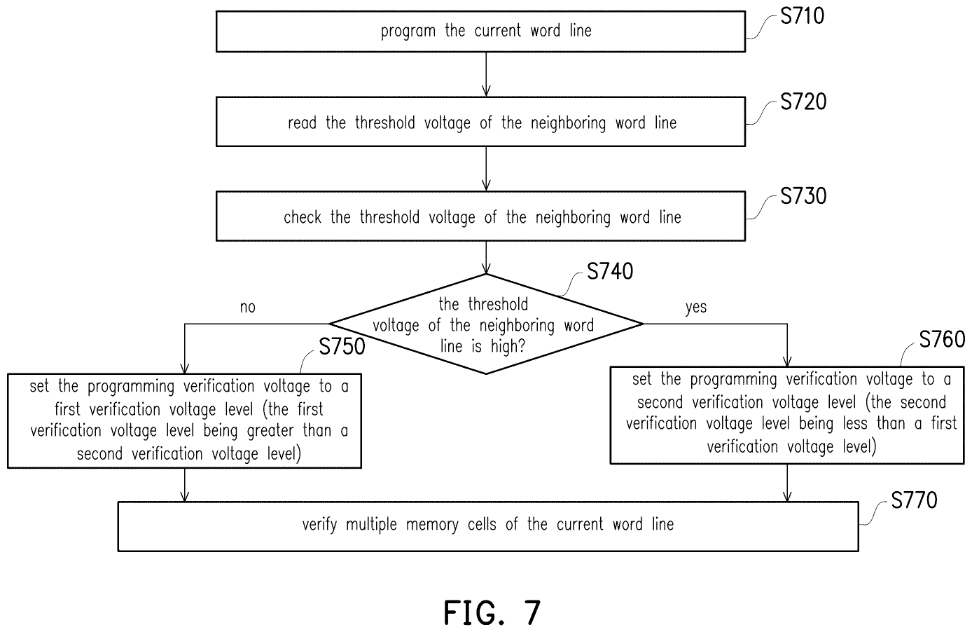

FIG. 7 is a flow chart of a programming method of a non-volatile memory according to yet another embodiment of the disclosure. The programming method described in FIG. 7 can be implemented by the non-volatile memory 100 in FIG. 1. The programming method described in FIG. 7 can be applied to memory devices with different memory cell types, such as multi-level memory cell (MLC) type, triple-level cell (TLC) type, or quad-level cell (QLC) type. Referring to FIG. 1 and FIG. 7, the control circuit 120 programs the memory cells of the current word line (e.g., the word line WLn) during the programming period. Generally speaking, a programming period includes multiple programming loops to perform increment-step-pulse-programming (ISPP) operations. Each programming loop includes a programming phase (step S710) and a programming verification phase (step S770). The control circuit 120 selects one of the programming loops to perform steps S720, S730, S740, S750, and S760. That is, during the programming period, the control circuit 120 only reads the threshold voltage of the neighboring word line in the selected programming loop.

In a selected programming loop among the programming loops of the programming period, the control circuit 120 programs multiple memory cells of the current word line (e.g., the word line WLn) (step S710). In a selected programming loop that programs multiple memory cells of the current word line, the control circuit 120 reads at least one threshold voltage of at least one neighboring word line (e.g., WLn−1 or WLn+1) adjacent to the current word line (step S720). In step S730, the control circuit 120 checks the at least one threshold voltage of the at least one neighboring word line. In the selected programming loop, and in other programming loops after the selected programming loop, the control circuit 120 can adjust the programming verification voltage used to verify the current word line according to the check result. That is, in other programming loops after the selected programming loop, the control circuit 120 does not need to read the threshold voltage of the neighboring word line adjacent to the current word line again.

In response to the threshold voltage of the neighboring word line (e.g., WLn−1) being judged to be low (the judgment result of step S740 is “No”), the control circuit 120 selects high verification voltage as the programming verification voltage of the current word line (e.g., the word line WLn) (step S750). Then, the control circuit 120 uses the programming verification voltage selected in step S750 to verify the memory cells of the current word line (step S770). On the contrary, in response to the threshold voltage of the neighboring word line (e.g., WLn−1) being judged to be high (the judgment result of step S740 is “yes”), the control circuit 120 selects low verification voltage as the programming verification voltage of the current word line (e.g., the word line WLn) (step S760). Then, the control circuit 120 uses the programming verification voltage selected in step S760 to verify the memory cell of the current word line (step S770).

For example, the control circuit 120 compares the threshold voltage of the neighboring word line (e.g., WLn−1) with a certain threshold to generate a check result. The threshold can be defined according to actual design and application. For example, the threshold may be the reference voltage (programming verification voltage) DV shown in FIG. 3. In response to the threshold voltage of the neighboring word line (e.g., WLn−1) being less than the threshold, the control circuit 120 sets the programming verification voltage for verifying the current word line (e.g., the word line WLn) to a first verification voltage level in step S750 (the first verification voltage level being greater than a second verification voltage level). In response to the threshold voltage of the neighboring word line (e.g., WLn−1) being greater than the threshold, the control circuit 120 sets the programming verification voltage for verifying the current word line (e.g., the word line WLn) to the second verification voltage level in step S760 (the second verification voltage level being less than the first verification voltage level).

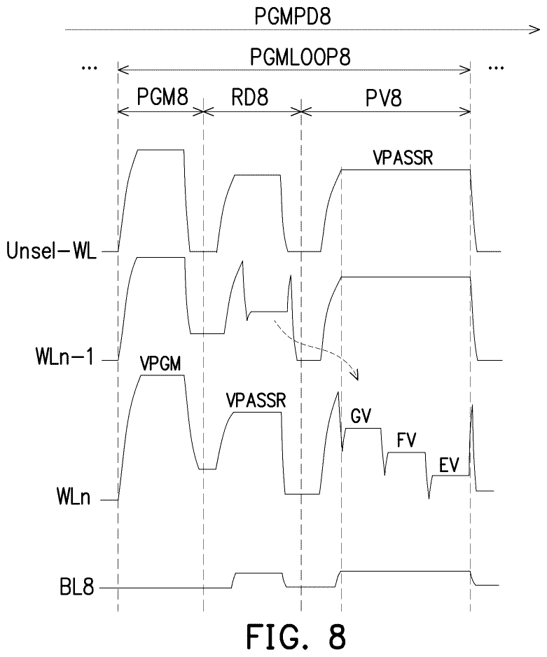

FIG. 8 is a schematic diagram of waveforms of a word line and a bit line according to an embodiment of the disclosure. The control circuit 120 programs the memory cells of the current word line (e.g., the word line WLn) in a programming period PGMPD8. The programming period PGMPD8 includes multiple programming loops. Each programming loop includes a programming phase (e.g., a programming phase PGM8 shown in FIG. 8) and a programming verification phase (e.g., a programming verification phase PV8 shown in FIG. 8). The control circuit 120 selects one of the programming loops as the selected programming loop, such as a programming loop PGMLOOP8 shown in FIG. 8. The control circuit 120 only adds additionally a reading phase RD8 to the selected programming loop PGMLOOP8 to read the threshold voltage of the neighboring word line (e.g., the word line WLn−1). FIG. 8 also shows the waveform of an unselected word line Unsel-WL for comparison. A programming voltage VPGM and a pass voltage VPASSR shown in FIG. 8 can be defined according to the actual design and application. A bit line BL8 shown in FIG. 8 can be a bit line, e.g., the bit lines BL1, BLn, or BLm, of the non-volatile memory 100.

In the programming phase PGM8 of the selected programming loop PGMLOOP8, the control circuit 120 programs multiple memory cells of the current word line WLn. In the reading phase RD8 of the selected programming loop PGMLOOP8, the control circuit 120 checks/reads the threshold voltage of the neighboring word line WLn−1 adjacent to the current word line WLn. In the programming verification phase PV8 of the selected programming loop PGMLOOP8 and other subsequent programming loops, the control circuit 120 can adjust the programming verification voltage used to verify the current word line WLn according to the threshold voltage (check result) of the neighboring word line WLn−1. In other programming loops after the selected programming loop PGMLOOP8, the control circuit 120 does not need to read the threshold voltage of the neighboring word line WLn−1 again.

In response to the threshold voltage of the neighboring word line WLn−1 being judged to be low, the control circuit 120 selects high verification voltage as the programming verification voltage of the current word line WLn. Then, the control circuit 120 uses the high verification voltage to verify the memory cells of the current word line WLn. On the contrary, in response to the threshold voltage of the neighboring word line WLn−1 being judged to be high, the control circuit 120 selects the low verification voltage as the programming verification voltage of the current word line WLn. Then, the control circuit 120 uses the low verification voltage to verify the memory cells of the current word line.

For example, each of the programming verification voltages AV to GV has a high voltage level (the original voltage level) and a low voltage level (a lower voltage level). In response to the threshold voltage of the neighboring word line WLn−1 being judged to be low, the control circuit 120 selects the high voltage level of the programming verification voltage corresponding to the potential states S1 to S7 that have not yet passed verification (e.g., the programming verification voltages EV, FV, and GV shown in FIG. 8). On the contrary, in response to the threshold voltage of the neighboring word line WLn−1 being judged to be high, the control circuit 120 selects the low voltage level of the programming verification voltages EV, FV, and GV that have not yet passed verification.

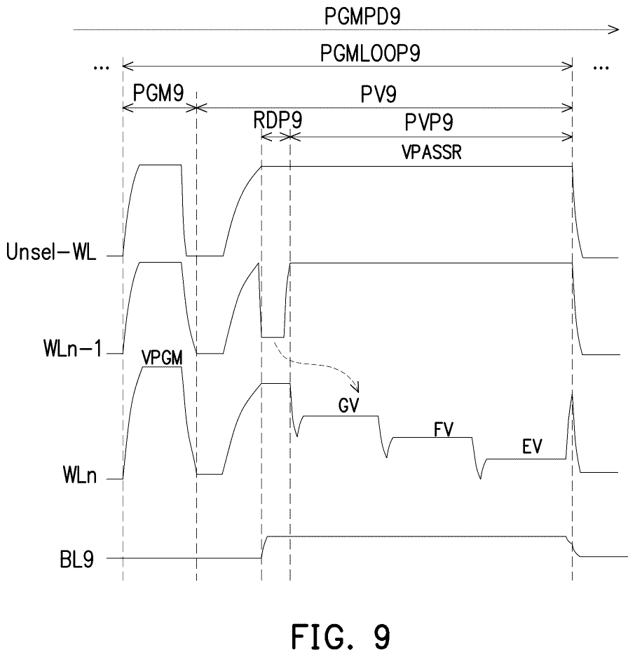

FIG. 9 is a schematic diagram of waveforms of a word line and a bit line according to another embodiment of the disclosure. The control circuit 120 programs the memory cells of the current word line (e.g., the word line WLn) in a programming period PGMPD9. The programming period PGMPD9 includes multiple programming loops. Each programming loop includes a programming phase (e.g., a programming phase PGM9 shown in FIG. 9) and a programming verification phase (e.g., a programming verification phase PV9 shown in FIG. 9). The control circuit 120 selects one of the programming loops as the selected programming loop, such as a programming loop PGMLOOP9 shown in FIG. 9. The programming verification phase PV9 of the selected programming loop PGMLOOP9 includes a reading period RDP9 and a programming verification period PVP9. The control circuit 120 only adds additionally a reading period RDP9 in the programming verification phase PV9 of the selected programming loop PGMLOOP9 to read the threshold voltage of the neighboring word line (e.g., the word line WLn−1). FIG. 9 also shows the waveform of an unselected word line Unsel-WL for comparison. A programming voltage VPGM and a pass voltage VPASSR shown in FIG. 9 can be defined according to the actual design and application. A bit line BL9 shown in FIG. 9 can be a bit line, e.g., the bit lines BL1, BLn, or BLm, of the non-volatile memory 100.

In the programming phase PGM9 of the selected programming loop PGMLOOP9, the control circuit 120 programs multiple memory cells of the current word line WLn. During the reading period RDP9 of the programming verification phase PV9 of the selected programming loop PGMLOOP9, the control circuit 120 checks/reads the threshold voltage of the neighboring word line WLn−1 adjacent to the current word line WLn. In the programming verification period PVP9 of the programming verification phase PV9 of the selected programming loop PGMLOOP9, and in the programming verification phase of other programming loops after the selected programming loop PGMLOOP9, the control circuit 120 can adjust the programming verification voltage used to verify the current word line WLn according to the threshold voltage (check result) of the neighboring word line WLn−1. In other programming loops after the selected programming loop PGMLOOP9, the control circuit 120 does not need to read the threshold voltage of the neighboring word line WLn−1 again.

In response to the threshold voltage of the neighboring word line WLn−1 being judged to be low, the control circuit 120 selects high verification voltage as the programming verification voltage of the current word line WLn. Then, the control circuit 120 uses the high verification voltage to verify the memory cells of the current word line WLn. On the contrary, in response to the threshold voltage of the neighboring word line WLn−1 being judged to be high, the control circuit 120 selects low verification voltage as the programming verification voltage of the current word line WLn. Then, the control circuit 120 uses the low verification voltage to verify the memory cells of the current word line. For example, in response to the threshold voltage of the neighboring word line WLn−1 being judged to be low, the control circuit 120 selects a high voltage level (the original voltage level) of the programming verification voltage corresponding to the potential states S1 to S7 that have not yet passed verification (e.g., the programming verification voltage EV, FV, and GV shown in FIG. 8). On the contrary, in response to the threshold voltage of the neighboring word line WLn−1 being judged to be high, the control circuit 120 selects a low voltage level (the lower voltage level) of the programming verification voltages EV, FV, and GV that have not yet passed verification.

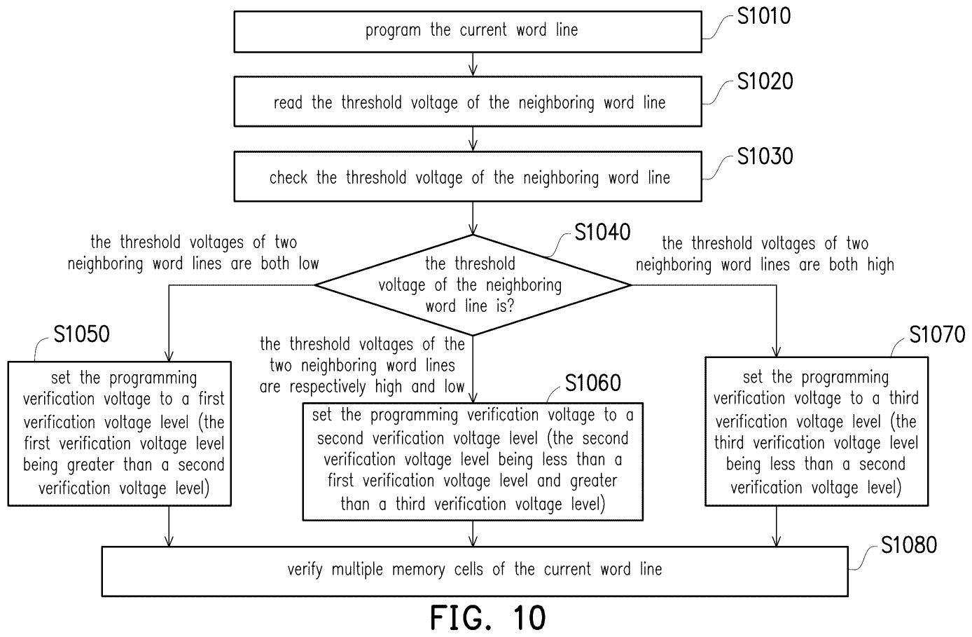

FIG. 10 is a flow chart of a programming method of a non-volatile memory according to another embodiment of the disclosure. The programming method described in FIG. 10 can be implemented by the non-volatile memory 100 in FIG. 1. The programming method described in FIG. 10 can be applied to memory devices with different memory cell types, such as multi-level memory cell (MLC) type, triple-level cell (TLC) type, or quad-level cell (QLC) type. Steps S1010, S1020, S1030, and S1080 shown in FIG. 10 can refer to the relevant description of steps S710, S720, S730 and S770 shown in FIG. 7 and make analogies, and therefore are not repeated in the following. Compared with the embodiment shown in FIG. 7, the embodiment shown in FIG. 10 determines the programming verification voltage of the current word line (e.g., the word line WLn) according to the threshold voltage of multiple neighboring word lines (e.g., WLn−1 and WLn+1).

Please refer to FIG. 1 and FIG. 10, in a selected programming loop among the programming loops of the programming period, the control circuit 120 programs multiple memory cells of the current word line (e.g., the word line WLn) (step S1010). In a selected programming loop that programs multiple memory cells of the current word line, the control circuit 120 reads the threshold voltage of multiple neighboring word lines (e.g., WLn−1 and WLn+1) adjacent to the current word line (step S1020). In step S1030, the control circuit 120 checks the threshold voltage of the neighboring word lines WLn−1 and WLn+1. For example, the control circuit 120 compares the threshold voltage of the neighboring word line WLn−1, the threshold voltage of the neighboring word line WLn+1, and the threshold to generate a check result. The threshold can be defined according to actual design and application. For example, the threshold may be the reference voltage Vref shown in FIG. 3. Based on actual design and application, the reference voltage Vref can be any voltage between S0~S7.

In response to the threshold voltage of the neighboring word line WLn−1 being less than the threshold, and in response to the threshold voltage of the neighboring word line WLn+1 being less than the threshold (the judgment result of step S1040 is that “the threshold voltages of two neighboring word lines are both low”), then the control circuit 120 sets the programming verification voltage of the current word line WLn to a first verification voltage level (the first verification voltage level being greater than a second verification voltage level and a third verification voltage level) (step S1050). For example, the control circuit 120 selects a high verification voltage as the programming verification voltage of the current word line WLn. Then, the control circuit 120 uses the high programming verification voltage selected in step S1050 to verify the memory cells of the current word line WLn (step S1080).

In response to the threshold voltage of the neighboring word line WLn−1 being less than the threshold, and in response to the threshold voltage of the neighboring word line WLn+1 being greater than the threshold (the judgment result of step S1040 is that “the threshold voltages of the two neighboring word lines are respectively high and low”), then the control circuit 120 sets the programming verification voltage of the current word line WLn to the second verification voltage level (the second verification voltage level being less than the first verification voltage level and greater than the third verification voltage level) (step S1060). For example, the control circuit 120 selects an intermediate verification voltage as the programming verification voltage of the current word line WLn. Then, the control circuit 120 uses an intermediate programming verification voltage selected in step S760 to verify the memory cell of the current word line WLn (step S1080).

In response to the threshold voltage of the neighboring word line WLn−1 being greater than the threshold, and in response to the threshold voltage of the neighboring word line WLn+1 being less than the threshold (the judgment result of step S1040 is that “the threshold voltages of the two neighboring word lines are respectively high and low”), then the control circuit 120 sets the programming verification voltage of the current word line WLn to the second verification voltage level (step S1060).

In response to the threshold voltage of the neighboring word line WLn−1 being greater than the threshold, and in response to the threshold voltage of the neighboring word line WLn+1 being greater than the threshold (the judgment result of step S1040 is that “the threshold voltages of the two neighboring word lines are both high”), then the control circuit 120 sets the programming verification voltage of the current word line WLn to the third verification voltage level (the third verification voltage level being less than the first verification voltage level and the second verification voltage level) (step S1070). For example, the control circuit 120 selects a low verification voltage as the programming verification voltage of the current word line WLn. Then, the control circuit 120 uses the low programming verification voltage selected in step S760 to verify the memory cell of the current word line WLn (step S1080).

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A non-volatile memory comprising:
a memory cell array comprising a plurality of memory cells, wherein each of a plurality of word lines is coupled to a plurality of memory cells in a corresponding row of the memory cells, and each of a plurality of bit lines is coupled to a plurality of memory cells in a corresponding column of the memory cells; and
a control circuit coupled to the memory cell array, wherein,
during a programming period for programming a plurality of memory cells of a current word line among the word lines, the control circuit reads at least one threshold voltage of at least one neighboring word line adjacent to the current word line among the word lines;
the control circuit checks the at least one threshold voltage of the at least one neighboring word line to generate a check result; and
based on the check result, the control circuit adjusts a programming verification voltage used to verify the current word line during the programming period.

2. The non-volatile memory according to claim 1, wherein the programming period comprises a plurality of programming loops,
the control circuit reads the at least one threshold voltage of the at least one neighboring word line in a selected programming loop among the plurality of programming loops; and
in the selected programming loop, and in other programming loops after the selected programming loop, the control circuit adjusts the programming verification voltage used to verify the current word line based on the check results.

3. The non-volatile memory according to claim 2, wherein during the programming period, the control circuit reads the at least one threshold voltage of the at least one neighboring word line only in the selected programming loop.

4. The non-volatile memory according to claim 2, wherein the selected programming loop comprises a programming phase, a reading phase, and a programming verification phase,
the control circuit programs the memory cells of the current word line in the programming phase,
the control circuit reads the at least one threshold voltage of the at least one neighboring word line in the reading phase, and
the control circuit adjusts the programming verification voltage for verifying the current word line according to the check result during the programming verification phase.

5. The non-volatile memory according to claim 2, wherein the selected programming loop comprises a programming phase and a programming verification phase, the programming verification phase comprises a reading period and a programming verification period,
the control circuit programs the memory cells of the current word line in the programming phase,
the control circuit reads the at least one threshold voltage of the at least one neighboring word line in the reading period of the programming verification phase, and
the control circuit adjusts the programming verification voltage for verifying the current word line according to the check result during the programming verification period of the programming verification phase.

6. The non-volatile memory according to claim 1, wherein the at least one neighboring word line comprises a first neighboring word line,
the control circuit compares a first threshold voltage of the first neighboring word line with a threshold value to generate the check result;
in response to the first threshold voltage being less than the threshold value, the control circuit sets the programming verification voltage for verifying the current word line to a first verification voltage level; and
in response to the first threshold voltage being greater than the threshold value, the control circuit sets the programming verification voltage for verifying the current word line to a second verification voltage level that is less than the first verification voltage level.

7. The non-volatile memory according to claim 1, wherein the at least one neighboring word line encompasses a first neighboring word line and a second neighboring word line,
the control circuit compares a first threshold voltage of the first neighboring word line, a second threshold voltage of the second neighboring word line, and a threshold value to generate the check result;
in response to the first threshold voltage being less than the threshold value, and in response to the second threshold voltage being less than the threshold value, the control circuit sets the programming verification voltage for verifying the current word line to a first verification voltage level;
in response to the first threshold voltage being less than the threshold value, and in response to the second threshold voltage being greater than the threshold value, the control circuit sets the programming verification voltage for verifying the current word line to a second verification voltage level that is less than the first verification voltage level;
in response to the first threshold voltage being greater than the threshold value, and in response to the second threshold voltage being less than the threshold value, the control circuit sets the programming verification voltage for verifying the current word line to the second verification voltage level; and
in response to the first threshold voltage being greater than the threshold value, and in response to the second threshold voltage being greater than the threshold value, the control circuit sets the programming verification voltage for verifying the current word line to a third verification voltage level that is less than the second verification voltage level.

8. A programming method adapted for a non-volatile memory, the programming method comprising:
reading at least one threshold voltage of at least one neighboring word line adjacent to a current word line during a programming period for programming a plurality of memory cells of the current word line;
checking the at least one threshold voltage of the at least one neighboring word line to generate a check result; and
adjusting a programming verification voltage used to verify the current word line during the programming period based on the check result.

9. The programming method according to claim 8, wherein the programming period comprises a plurality of programming loops, and the programming method further comprises:
reading the at least one threshold voltage of the at least one neighboring word line in a selected programming loop among the plurality of programming loops; and
in the selected programming loop, and in other programming loops after the selected programming loop, adjusting the programming verification voltage used to verify the current word line based on the check results.

10. The programming method according to claim 9, wherein during the programming period, the at least one threshold voltage of the at least one neighboring word line is read only in the selected programming loop.

11. The programming method according to claim 9, wherein the selected programming loop comprises a programming phase, a reading phase, and a programming verification phase, and the programming method further comprises:
programming the memory cells of the current word line in the programming phase;
reading the at least one threshold voltage of the at least one neighboring word line in the reading phase; and
adjusting the programming verification voltage for verifying the current word line according to the check result during the programming verification phase.

12. The programming method according to claim 9, wherein the selected programming loop comprises a programming phase and a programming verification phase, the programming verification phase comprises a reading period and a programming verification period, and the programming method further comprises:
programming the memory cells of the current word line in the programming phase;
reading the at least one threshold voltage of the at least one neighboring word line during the reading period of the programming verification phase; and
adjusting the programming verification voltage for verifying the current word line according to the check result during the programming verification period of the programming verification phase.

13. The programming method according to claim 8, wherein the at least one neighboring word line comprises a first neighboring word line, and the programming method further comprises:
comparing a first threshold voltage of the first neighboring word line with a threshold value to generate the check result;
in response to the first threshold voltage being less than the threshold value, setting the programming verification voltage for verifying the current word line to a first verification voltage level; and
in response to the first threshold voltage being greater than the threshold value, setting the programming verification voltage for verifying the current word line to a second verification voltage level that is less than the first verification voltage level.

14. The programming method according to claim 8, wherein the at least one neighboring word line comprises a first neighboring word line and a second neighboring word line, and the programming method further comprises:
comparing a first threshold voltage of the first neighboring word line, a second threshold voltage of the second neighboring word line, and a threshold value to generate the check result;
in response to the first threshold voltage being less than the threshold value, and in response to the second threshold voltage being less than the threshold value, setting the programming verification voltage for verifying the current word line to a first verification voltage level;
in response to the first threshold voltage being less than the threshold value, and in response to the second threshold voltage being greater than the threshold value, setting the programming verification voltage for verifying the current word line to a second verification voltage level that is less than the first verification voltage level;
in response to the first threshold voltage being greater than the threshold value, and in response to the second threshold voltage being less than the threshold value, setting the programming verification voltage for verifying the current word line to the second verification voltage level; and
in response to the first threshold voltage being greater than the threshold value, and in response to the second threshold voltage being greater than the threshold value, setting the programming verification voltage for verifying the current word line to a third verification voltage level that is less than the second verification voltage level.
